(19) United States
(12) Patent Application Publication
(10) Pub. No.: US 2025/0391825 A1
(43) Pub. Date: Dec. 25, 2025

(54) SEMICONDUCTOR PACKAGE WITH UNEVEN STACKED DIES

(71) Applicant: Micron Technology, Inc., Boise, ID (US)

(72) Inventors: Chin Hui CHONG, Singapore (SG); Soon Sing NG, Seletar (SG); Amirul Afiq HUD, Iskandar Puteri Johor (MY)

(21) Appl. No.: 19/180,594

(22) Filed: Apr. 16, 2025

Related U.S. Application Data
(60) Provisional application No. 63/658,623, filed on Jun. 11, 2024.

(51) Int. Cl. H01L 25/18; H01L 23/00; H01L 25/00; H10B 80/00; H10D 80/30

(52) U.S. Cl. CPC H01L 25/18; H01L 24/48; H01L 25/50; H10B 80/00; H10D 80/30; H01L 24/32; H01L 24/73; H01L 2224/32145; H01L 2224/32225; H01L 2224/48091; H01L 2224/48227; H01L 2224/73265; H01L 2225/0651; H01L 2225/06524; H01L 2225/06562; H01L 2924/1438

(57) ABSTRACT

Implementations described herein relate to various semiconductor device assemblies. In some implementations, a semiconductor device assembly includes a first stack of first semiconductor dies on a substrate, wherein the first stack has a first stepped profile that extends above the substrate and toward a central axis of the substrate; a second stack of second semiconductor dies on the substrate, wherein the second stack has a second stepped profile that extends above the substrate and toward the central axis of the substrate; and a tapered wire bond zone between the first stack and the second stack, wherein a width of the tapered wire bond zone away from a surface of the substrate is greater than a width of the tapered wire bond zone proximate the surface of the substrate.

### CROSS-REFERENCE TO RELATED APPLICATION

This patent application claims priority to U.S. Provisional Patent Application No. 63/658,623, filed on Jun. 11, 2024, entitled “SEMICONDUCTOR PACKAGE WITH UNEVEN STACKED DIES,” and assigned to the assignee hereof. The disclosure of the prior application is considered part of and is incorporated by reference into this patent application.

### TECHNICAL FIELD

The field of semiconductor packaging pertains to the methods and materials used to safeguard integrated circuit chips and facilitate their functional integration into electronic systems. This domain encompasses a variety of techniques aimed at enhancing the physical configuration and connectivity of these components within electronic devices.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram illustrating an example implementation described herein.

FIG. 4 is a flowchart of an example method of forming an integrated assembly or memory device having uneven stacked dies described herein.

FIG. 5 is a flowchart of an example method of forming an integrated assembly or memory device having uneven stacked dies described herein.

FIG. 6A through FIG. 6E are diagrammatic views showing formation of a portion of an apparatus having uneven stacked dies at example process stages of an example process of forming the portion.

### DETAILED DESCRIPTION

In the field of semiconductor device packaging, there is an ongoing drive to increase the density of semiconductor dies within a semiconductor package while maintaining or reducing the semiconductor package's physical dimensions (e.g., a footprint and/or a thickness of the semiconductor package). This miniaturization effort enables the development of compact and high-performance electronic devices.

One of the challenges faced in this technical field is accommodating an increase in a quantity of semiconductor dies without exceeding thickness and/or footprint thresholds imposed by end-use markets. A direct shingle stacking approach with a high semiconductor die count can lead to difficulties in wire bonding, particularly for the inner dies, due to tight proximity and potential physical interference with adjacent die stacks. This issue becomes more pronounced as the semiconductor die count increases and can drive an increase in the footprint to provide an adequate bonding margin, thus conflicting with the goal of maintaining or reducing the overall size of the semiconductor package.

Moreover, some die stacking techniques do not adequately address wire bonding challenges (e.g., shapes and/or routing paths of wire bonds), presenting a technical barrier to achieving higher density semiconductor packages that are manufacturable using available semiconductor manufacturing tools and/or processes. Therefore, there is a need for improved semiconductor packaging solutions that enable increased semiconductor die counts while addressing the wire bonding challenges and satisfying dimensional thresholds.

Some implementations described herein provide a semiconductor package that enables an increased semiconductor die count while managing challenges of wire bonding in tight spaces. The semiconductor package includes a substrate with a first integrated circuit having a first overall height with stacked semiconductor dies that are progressively staggered toward a central axis of the substrate. A second integrated circuit with a lesser overall height includes similarly stacked semiconductor dies and is located between the first integrated circuit and the central axis. This configuration, along with the use of different die thicknesses for the inner and outer stacks, allows for a tapered wire bond zone that increases in width as it extends away from the substrate, facilitating improved wire bonding clearance and margin.

In some aspects, the semiconductor package includes additional integrated circuits on the opposite side of the central axis, maintaining the same approximate overall heights as the first and second integrated circuits, and possibly a fifth integrated circuit between the second and fourth integrated circuits. The tapered wire bond zone is further enhanced by the use of different widths for the offsets that create the stepped profiles of the stacked semiconductor dies.

The use of different die thicknesses for inner and outer stacks provides more wire margin clearance, which is particularly beneficial for the inner stacks where wire bonding is more challenging due to tighter proximity. Furthermore, the use of the different die thicknesses for the inner and outer stacks may enable satisfying one or more dimensional thresholds (e.g., the footprint and/or thickness) imposed by end-use markets.

In this way, an amount of resources used to support a market consuming the semiconductor package (e.g., raw materials, semiconductor manufacturing tools, labor, and/or computing resources) is reduced. Furthermore, the invention provides a technical solution that achieves space efficiency and meets the technical demand for increased data storage capacity in electronic devices.

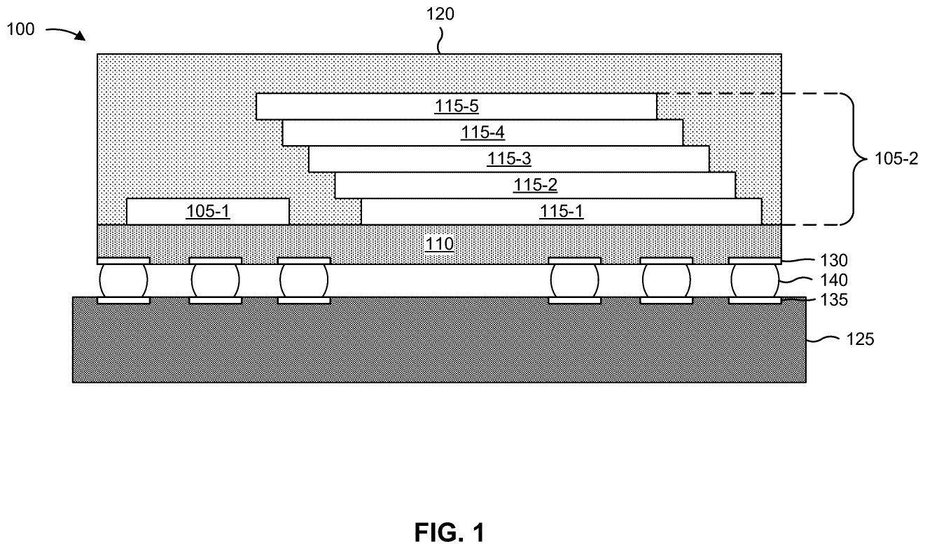

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

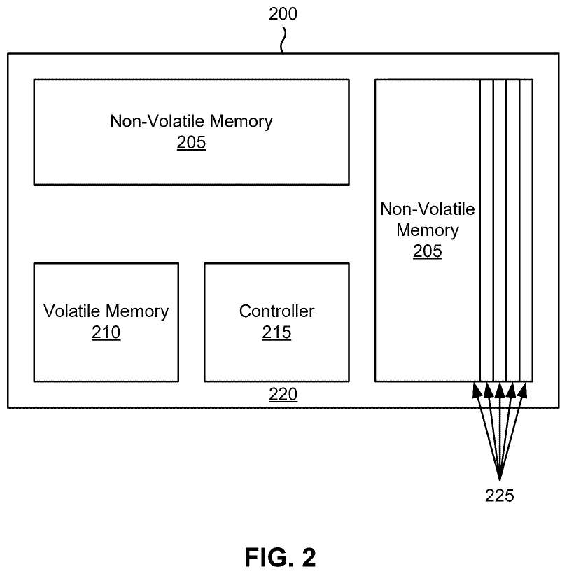

As described in greater detail in connection with FIG. 2 through FIG. 6E, the apparatus 100 may include additional integrated circuits 105 and/or stacks of dies 115. Furthermore, the apparatus 100 may include tapered wire bond zones between the integrated circuits 105 and/or the stacks of dies 115.

As indicated above, FIG. 1 is provided as an example. Other examples may differ from what is described with regard to FIG. 1.

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

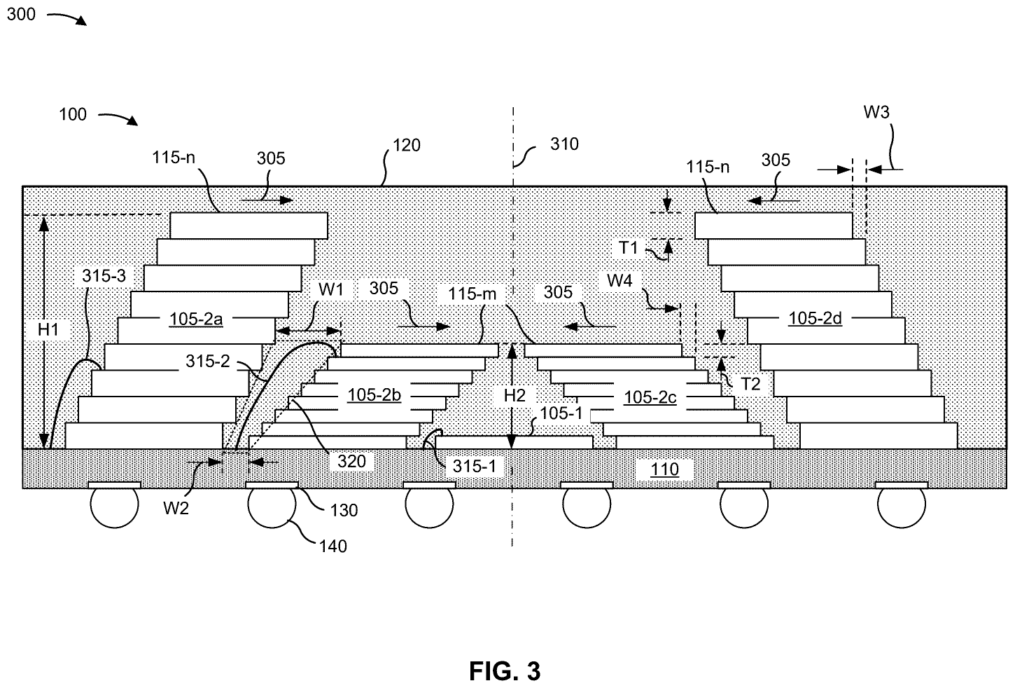

As described in greater detail in connection with FIG. 3 through FIG. 6E, the non-volatile memory 205 may include NAND memory. Additionally, or alternatively, the memory device 200 may include multiple stacks of the stacked semiconductor dies 225. In some implementations, the multiple stacks have different heights and/or stepped (e.g., shingled) profiles that contribute to forming tapered wire bond zones between adjacent stacks.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIG. 3 is a diagram illustrating an example implementation 300 described herein. The implementation 300 may include one or more portions of the apparatus 100 of FIG. 1. Additionally, or alternatively, one or more aspects of the implementation 300 may be included as part of the memory device 200 of FIG. 2.

As shown in the side section view of FIG. 3, the apparatus 100 includes the integrated circuit 105-1, the integrated circuit 105-2a, the integrated circuit 105-2b, the integrated circuit 105-2c, and the integrated circuit 105-2d. In some implementations, the integrated circuit 105-1 (e.g., a die 115) includes controller integrated circuitry. The integrated circuits 105-2a and 105-2d may each include a stack of dies 115-n, where each die of the stack of dies 115-n includes memory integrated circuitry (e.g., NAND memory integrated circuitry). The integrated circuits 105-2b and 105-2c may each include a stack of dies 115-m, where each die of the stack of dies 115-m includes memory integrated circuitry (e.g., NAND memory integrated circuitry).

Each of the integrated circuits 105-2a and 105-2d (each stack of dies 115-n) may include a stepped profile that extends above the substrate 110 and in a direction 305 that is toward a central axis 310. In other words, the stack of dies 115-n may be a shingled stack that extends upwardly from the substrate 110 and that progressively staggers toward the central axis 310.

In some implementations, the integrated circuit 105-2a and the integrated circuit 105-2d have a same quantity of dies 115-n and a same approximate overall height H1 (e.g., a same nominal height with differences limited to variations in semiconductor manufacturing process and/or tool capabilities). Alternatively, and in some implementations, the integrated circuit 105-2a and the integrated circuit 105-2d may have a different quantity of dies 115-n (and different overall heights).

Furthermore, and as shown in FIG. 3, each of the integrated circuits 105-2b and 105-2c (each stack of dies 115-m) may include a stepped profile that extends above the substrate 110 and in the direction 305 that is toward the central axis 310. In other words, the stack of dies 115-m may be a shingled stack that extends upwardly from the substrate 110 and is progressively staggered toward the central axis 310.

In some implementations, the integrated circuit 105-2b and the integrated circuit 105-2c have a same quantity of dies 115 and same approximate overall height H2 (e.g., a same nominal height with differences limited to variations in semiconductor manufacturing process and/or tool capabilities), where H2 is less than or equal to H1. Alternatively, and in some implementations, the integrated circuit 105-2b and the integrated circuit 105-2c may have a different quantity of dies 115 (and different overall heights).

In some implementations, the integrated circuit 105-2a and the integrated circuit 105-2b have a same quantity of dies 115. In some implementations, the integrated circuit 105-2a and the integrated circuit 105-2b have different quantities of dies 115.

In some implementations, the integrated circuit 105-2b (e.g., an inner stack of dies 115) is between the integrated circuit 105-2a (e.g., an outer stack of dies 115) and the central axis. Additionally, or alternatively, the integrated circuit 105-2a is between the integrated circuit 105-2b and an edge of the substrate 105-2a. Additionally, or alternatively, at least a portion of the integrated circuit 105-2b may overlap and/or overhang the integrated circuit 105-1. Additionally, or alternatively, the integrated circuit 105-1 may be adjacent to a side of the integrated circuit 105-2 (e.g., the stack of dies 115-m) that faces the central axis 310.

The apparatus 100 may further include one or more wire bonds 315. As shown in FIG. 3, at least one wire bond 315-1 may electrically couple the integrated circuit 105-1 with the substrate 110. Additionally, or alternatively, at least one wire bond 315-2 may electrically couple the integrated circuit 105-2b (e.g., at least one die 115 included in the stack of dies 115-m) with the substrate 110. Additionally, or alternatively, at least one wire bond 315-3 may electrically couple the integrated circuit 105-2c (e.g., at least one die 115 included in the stack of dies 115-n) with the substrate 110. Additional wire bonds 315 that may be included in the apparatus 100 are excluded from FIG. 3 for clarity.

In some implementations, the integrated circuits 105-2a and 105-2b (and/or the integrated circuits 105-2c and 105-2d) may have one or more dimensional properties that, in combination with respective stepped profiles, create a tapered wire bond zone 320. The tapered wire bond zone 320 may have a width W1 away from the substrate 110 is greater than a width W2 proximate the substrate 110. The difference in the width W1 and the width W2 may increase a wire bond margin for the wire bond 315-2. Within the tapered wire bond zone 320, the casing 120 (e.g., an epoxy mold compound) may surround the wire bond 315-2. As shown in FIG. 3, and in some implementations, the tapered wire bond zone 320 is between the outward facing profile of the integrated circuit 105-2b and the inward facing profile of the integrated circuit 105-2a.

To create the tapered wire bond zone 320, each of the dies 115-n may have a thickness T1 and each of the dies 115-m may have a thickness T2, where T2 is less than T1. As an example, the thickness T1 may be approximately 80 microns, and the thickness T2 may be approximately 45 microns. Additionally, or alternatively, a ratio of the thickness T1 to the thickness T2 (T1:T2) may be within a range of approximately 9:16 to approximately 11:16. If the ratio T1:T2 is less than approximately 9:16, thickness and/or a robustness of the dies 115-m may be reduced, which may decrease a quality and/or a reliability of the integrated circuit 105-2b. If the ratio T1:T2 is between approximately 9:16 and approximately 11:16, the thickness and/or robustness of the dies 115-m may be such that the integrated circuit 105-2b satisfies a quality and/or a reliability threshold. Furthermore, the tapered wire bond zone 320 may provide sufficient clearance for the wire bond 315-2 (e.g., wire bond margin) to avoid interference with integrated circuit 105-2a (e.g., the dies 115-n). If the ratio T1:T2 is greater than approximately 11:16, the tapered wire bond zone 320 may fail to provide sufficient clearance between wire bond 315-2 and the integrated circuit 105-2a. However, other values and ranges for the thicknesses T1, T2, and the ratio T1:T2 are within the scope of the present disclosure.

Other example dimensional properties include a width W3 of offsets used to create the staggered profile of the integrated circuit 105-2a and a width W4 of offsets used to create the staggered profile of the integrated circuit 105-2b. In some implementations, the width W4 is less than or equal to the width W3.

As indicated above, FIG. 3 is provided as an example. Other examples may differ from what is described with regard to FIG. 3.

As described in connection with FIG. 1 through FIG. 3, and in some implementations, a semiconductor device assembly (e.g., the apparatus 100 or the memory device 200) includes a substrate (e.g., the substrate 110) and a first integrated circuit (e.g., the integrated circuit 105-2a) on the substrate having a first overall height (e.g., the height H1). The first integrated circuit may include first semiconductor dies (e.g., the dies 115-n) that are stacked and progressively staggered toward a central axis (e.g., the central axis 310) of the substrate. Furthermore, the semiconductor device assembly includes a second integrated circuit (e.g., the integrated circuit 105-2b) on the substrate having a second overall height (e.g., the height H2) that is less than the first overall height. The second integrated circuit may be between the first integrated circuit and the central axis and may include second semiconductor dies (e.g., the dies 11-5m) that are stacked and progressively staggered toward the central axis.

Additionally, or alternatively and in some implementations, a semiconductor device assembly (e.g., the apparatus 100 or the memory device 200) includes a first stack of first semiconductor dies (e.g., the integrated circuit 105-2 including the dies 115-n) on a substrate (e.g., the substrate 110). The first stack may have a first stepped profile that extends above the substrate and toward a central axis (e.g., the central axis 310) of the substrate. Furthermore, the semiconductor device assembly may include a second stack of second semiconductor dies (e.g., the integrated circuit 105-2 including the dies 115-n) on the substrate. The second stack may have a second stepped profile that extends above the substrate and toward the central axis of the substrate. Furthermore, the semiconductor device assembly includes a tapered wire bond zone (e.g., the tapered wire bond zone 320) between the first stack and the second stack. A width (e.g., the width W1) of the tapered wire bond zone away from a surface of the substrate may be greater than a width (e.g., the width W2) of the tapered wire bond zone proximate the surface of the substrate.

Additionally, or alternatively and in some implementations, an apparatus (e.g., the apparatus 100) includes a substrate (e.g., the substrate 110) having a central axis (e.g., the central axis 310). The apparatus includes a first stack of first NAND memory dies (e.g., the integrated circuit 105-2a including the dies 115-n) that extends upwardly from the substrate. The first NAND memory dies may be progressively staggered toward the central axis and may each have a first thickness (e.g., the thickness T1). Furthermore, the apparatus may include a second stack of second NAND memory dies (e.g., the integrated circuit 105-2a including the dies 115-m) that extends upwardly from the substrate. The second stack may be between the first stack and the central axis. The NAND memory dies may be progressively staggered toward the central axis and may each have a second thickness (T2) that is less than the first thickness.

The use of different die thicknesses, stack heights, staggering, and/or profiles as described in connection with FIG. 1 through FIG. 3 may increase a wire bond margin clearance, which is particularly beneficial for the inner stacks, where wire bonding is more challenging due to tighter proximity. Furthermore, the use of different die thicknesses, stack heights, staggering, and/or profiles may achieve space efficiencies that meet the technical demand for increased data storage capacity in electronic devices. In these ways, an amount of resources used to support a market consuming the semiconductor device assembly and/or the apparatus (e.g., raw materials, semiconductor manufacturing tools, labor, and/or computing resources) is reduced.

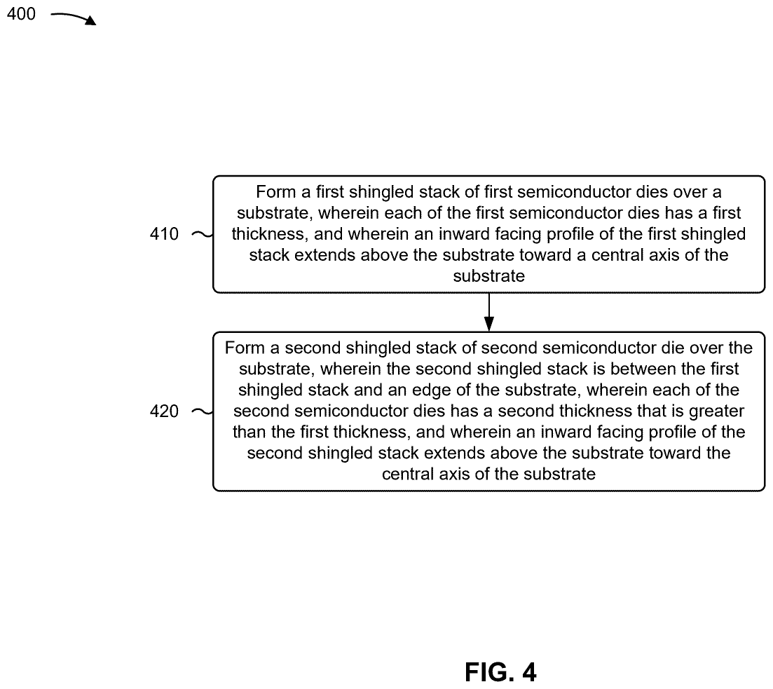

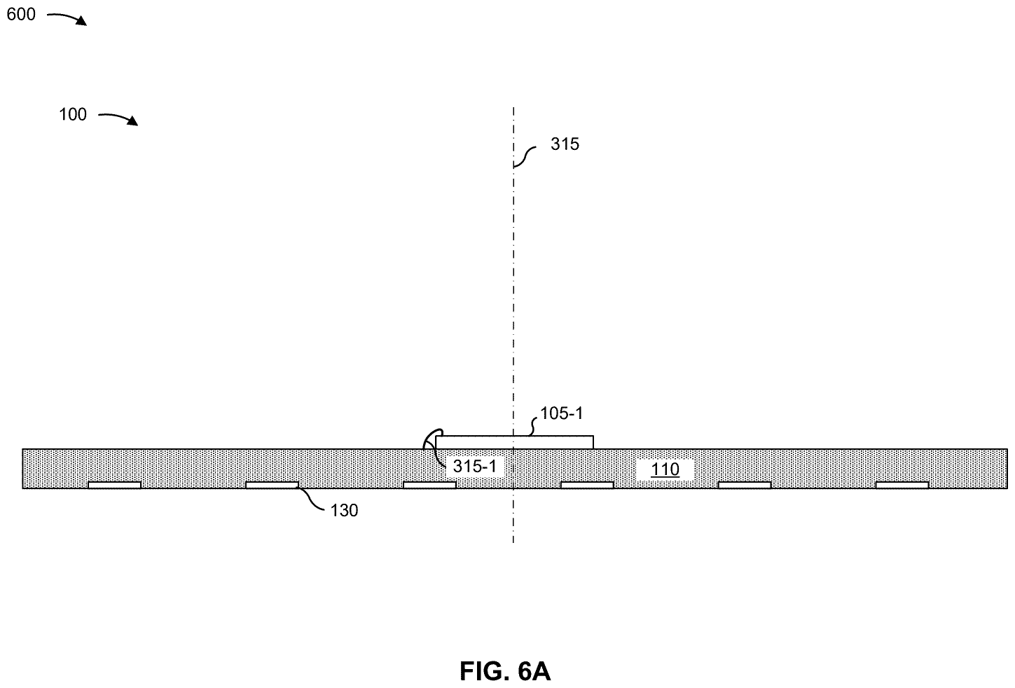

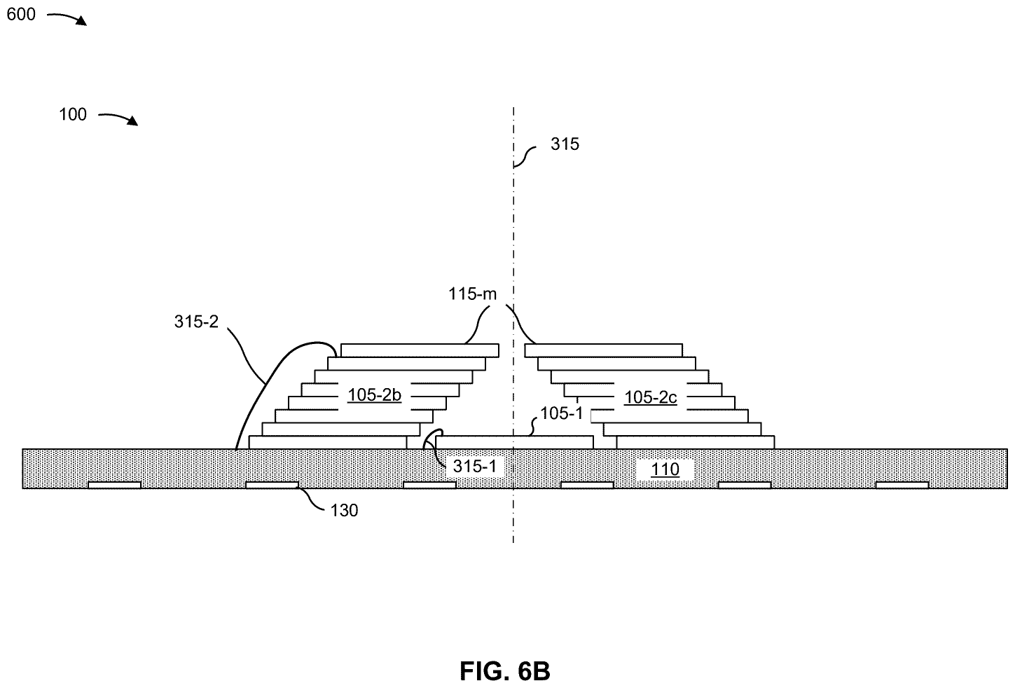

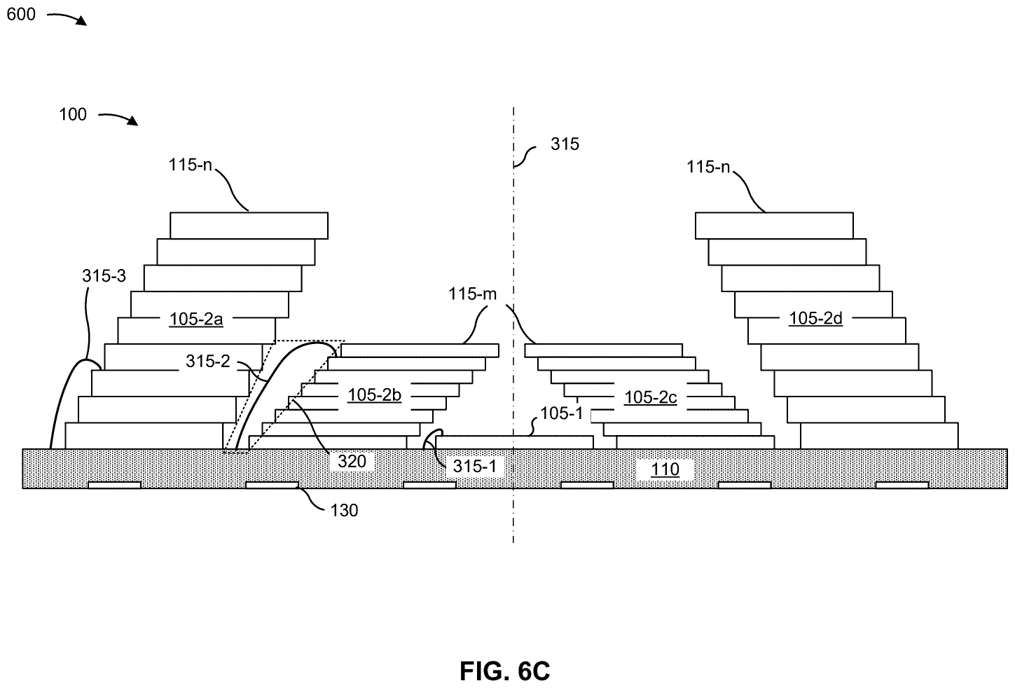

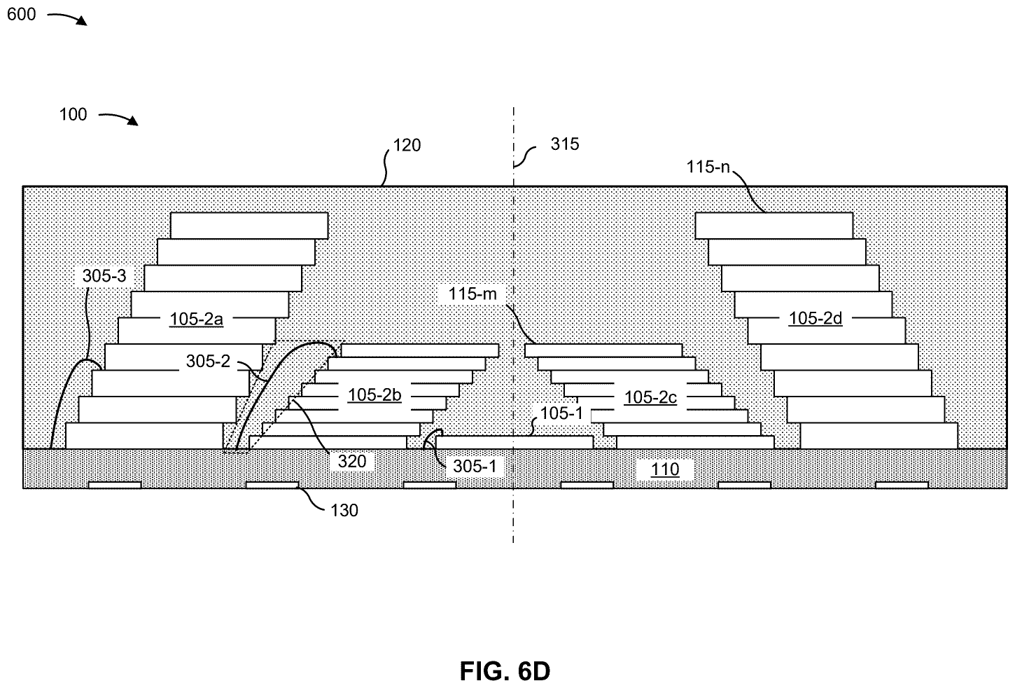

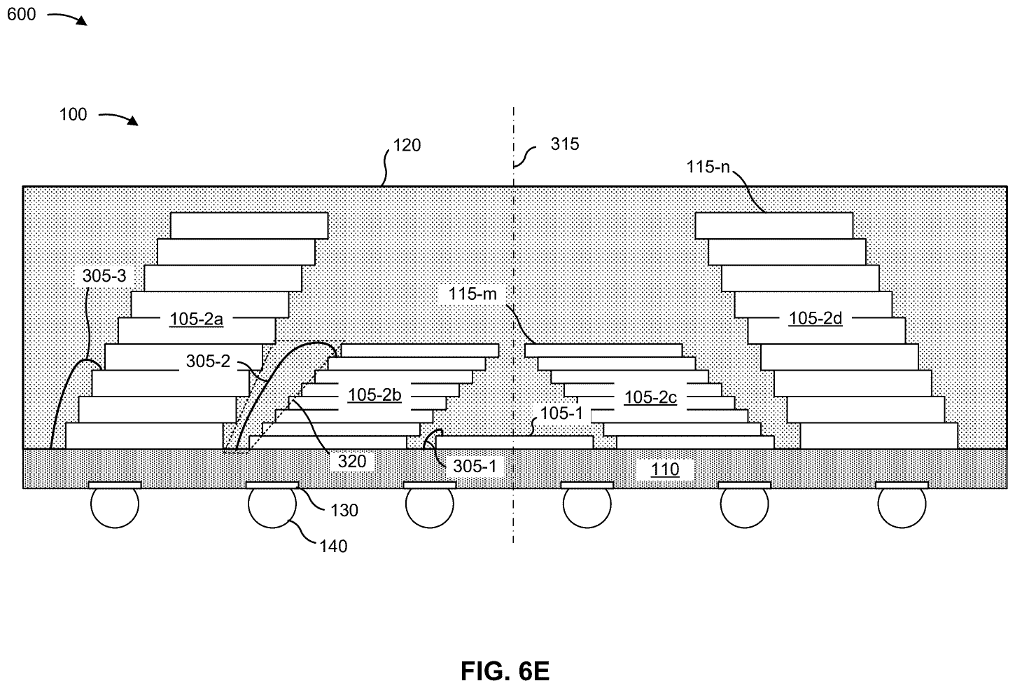

FIG. 4 is a flowchart of an example method 400 of forming an integrated assembly or memory device having uneven stacked dies described herein. In some implementations, and as described in greater detail in connection with FIG. 6A through FIG. 6E, one or more process blocks of FIG. 4 may be performed by various semiconductor manufacturing equipment.

As shown in FIG. 4, the method 400 may include forming a first shingled stack of first semiconductor dies (e.g., the integrated circuit 105-2b including the stack of dies 115-m) over a substrate (e.g., the substrate 110), wherein each of the first semiconductor dies has a first thickness (e.g., the thickness T2), and wherein an inward facing profile of the first shingled stack extends above the substrate toward a central axis (e.g., the central axis 310) of the substrate (block 410). As further shown in FIG. 4, the method 400 may include forming a second shingled stack of second semiconductor dies (e.g., the integrated circuit 105-2a including the stack of dies 115-n) over the substrate, wherein the second shingled stack is between the first shingled stack and an edge of the substrate, wherein each of the second semiconductor dies has a second thickness (e.g., the thickness T1) that is greater than the first thickness, and wherein an inward facing profile of the second shingled stack extends above the substrate toward the central axis of the substrate (block 420).

The method 400 may include additional aspects, such as any single aspect or any combination of aspects described below and/or in connection with one or more other methods described elsewhere herein.

In a first aspect, forming the first shingled stack includes joining at least two of the first semiconductor dies using a die attach process that uses a die attach film.

In a second aspect, alone or in combination with the first aspect, forming the second shingled stack includes joining at least two of the second semiconductor dies using a die attach process that uses a die attach film.

In a third aspect, alone or in combination with one or more of the first and second aspects, forming the first shingled stack includes sequentially joining the first semiconductor dies using first offsets having a first width (e.g., the width W4), and forming the second shingled stack includes sequentially joining the second semiconductor dies using second offsets having a second width (e.g., the width W3), wherein the second width is greater than or equal to the first width.

In a fourth aspect, alone or in combination with one or more of the first through third aspects, forming the second shingled stack includes forming a tapered wire bond zone (e.g., the tapered wire bond zone 320) between an outward facing profile of the first shingled stack and the inward facing profile of the second shingled stack.

In a fifth aspect, alone or in combination with one or more of the first through fourth aspects, the method 400 includes forming a wire bond (e.g., the wire bond 315-2) that electrically couples at least one of the first semiconductor dies with the substrate prior to forming the tapered wire bond zone.

In a sixth aspect, alone or in combination with one or more of the first through fifth aspects, the method 400 includes forming a casing (e.g., the casing 120) that surrounds the wire bond with an epoxy mold compound and that fills the tapered wire bond zone with the epoxy mold compound.

In a seventh aspect, alone or in combination with one or more of the first through sixth aspects, the first semiconductor dies and the second semiconductor dies are NAND memory dies, and the method 400 includes attaching a controller die (e.g., the integrated circuit 105-1) to the substrate prior to forming the first shingled stack.

In an eighth aspect, alone or in combination with one or more of the first through seventh aspects, attaching the controller die to the substrate includes attaching the controller die to the substrate using a surface mount process.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the apparatus 100, an integrated assembly that includes the apparatus 100, any part described herein of apparatus 100, and/or any part described herein of an integrated assembly that includes the apparatus 100. For example, the method 400 may include forming one or more of the integrated circuits 105 (e.g., the stacked dies 115 having the stepped profile) or the tapered wire bond zone 320.

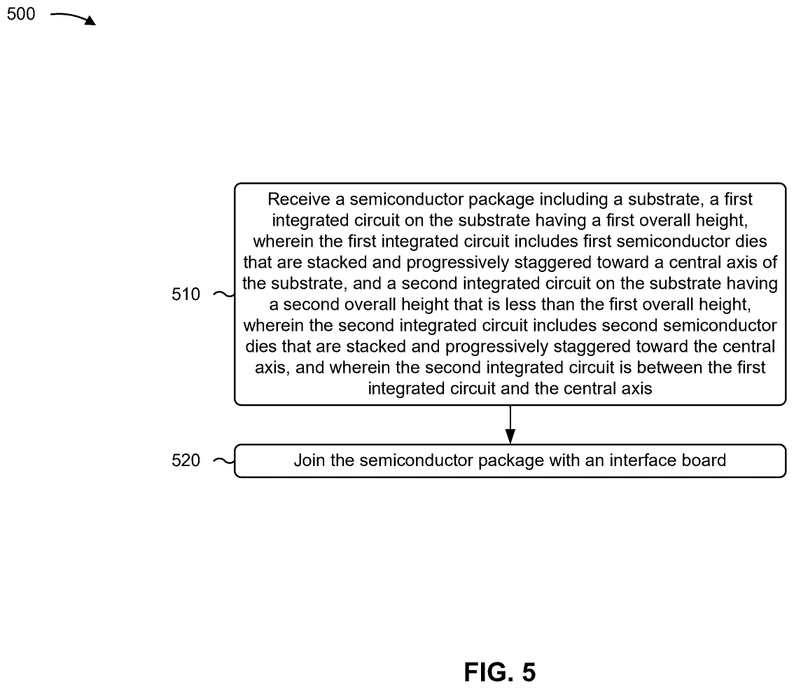

FIG. 5 is a flowchart of an example method 500 of forming an integrated assembly or memory device having uneven stacked dies described herein. In some implementations, and as described in greater detail in connection with FIG. 6A through FIG. 6E, one or more process blocks of FIG. 5 may be performed by various semiconductor manufacturing equipment.

As shown in FIG. 5, the method 500 may include receiving a semiconductor package (e.g., the apparatus 100). The semiconductor package may include a substrate (e.g., the substrate 110) and a first integrated circuit (e.g., the integrated circuit 105-2a) on the substrate having a first overall height (e.g., the overall height H1), wherein the first integrated circuit includes first semiconductor dies (e.g., the stack of dies 115-n) that are stacked and progressively staggered toward a central axis (e.g., the central axis 310) of the substrate. The semiconductor package may include a second integrated circuit (e.g., the integrated circuit 105-2b) on the substrate having a second overall height (e.g., the overall height H2) that is less than the first overall height, wherein the second integrated circuit includes second semiconductor dies (e.g., the stack of dies 115-m) that are stacked and progressively staggered toward the central axis, and wherein the second integrated circuit is between the first integrated circuit and the central axis (block 510). As further shown in FIG. 5, the method 500 may include joining the semiconductor package with an interface board (e.g., the substrate 220) (block 520).

The method 500 may include additional aspects, such as any single aspect or any combination of aspects described below and/or in connection with one or more other methods described elsewhere herein.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the memory device 200, an integrated assembly that includes the memory device 200, any part described herein of memory device 200, and/or any part described herein of an integrated assembly that includes the memory device 200. For example, the method 500 may include forming one or more of the apparatus 100, the integrated circuits 105 (e.g., the stacked dies 115 having the stepped profile), or the tapered wire bond zone 320.

FIG. 6A through FIG. 6E are diagrammatic views showing formation of a portion of an apparatus (e.g., the apparatus 100) having uneven stacked dies at example process stages of an example process 600 of forming the portion. In some implementations, the example method 500 described below in connection with FIGS. 6A through 6E may correspond to the method 400, one or more blocks of the method 400, the method 500, and/or one or more blocks of the method 500. However, the process 600 described below is an example, and other example processes may be used to form the apparatus 100, an integrated assembly that includes the apparatus 100, and/or one or more parts of the apparatus 100 and/or the integrated assembly.

As shown in FIG. 6A, the process 600 may include placing the integrated circuit 105-1 (e.g., a controller die) over and/or on the substrate 110. As an example, and in some implementations, placing the integrated circuit 105-1 over and/or on the substrate 110 includes using a pick and place tool to join the integrated circuit 105-1 with the substrate 110 using a die attach film. Alternatively, placing the integrated circuit 105-1 over and/or on the substrate may include using a set of surface mount (SMT) tools to join the integrated circuit 105-1 with the substrate using a surface mount operation (e.g., the integrated circuit 105-1 may be a flip chip die, and the set of SMT tools may solder the integrated circuit 105-1 to the substrate 110 using a reflow process). Furthermore, and as shown in FIG. 6A, the process 600 may include using a wire bond tool to form at least one wire bond (e.g., the wire bond 315-1) that electrically couples the integrated circuit 105-1 with the substrate 110.

As shown in FIG. 6B, the process 600 may include forming a first shingled stack (e.g., the integrated circuit 105-2b or the integrated circuit 105-2c including the stack of dies 115-m) over and/or on the substrate 110. As an example, and in some implementations, forming the first shingled stack over and/or on the substrate 110 includes using a pick and place tool to sequentially join one or more dies of the stack dies 115-m using first offsets as described in connection with FIG. 3 (e.g., the offsets having the width W3). The first offsets, in combination with a first thickness of one or more dies of the stack of dies 115-m as described in connection with FIG. 3 (e.g., the thickness T2), may form an inward facing profile that extends above the substrate 110 toward the central axis 310. In some implementations, using the pick and place tool to form the first shingled stack includes using a die attach film to join dies included in the stack of dies 115-m. Furthermore, and as shown in FIG. 6B, the process 600 may include using a wire bond tool to form at least one wire bond (e.g., the wire bond 315-2) that electrically couples the first shingled stack with the substrate 110.

As shown in FIG. 6C, the process 600 may include forming a second shingled stack (e.g., the integrated circuit 105-2a or the integrated circuit 105-2d including the stack of dies 115-n) over and/or on the substrate 110. As an example, and in some implementations, forming the second shingled stack over and/or on the substrate 110 includes using a pick and place tool to sequentially join one or more dies of the stack dies 115-n using second offsets as described in connection with FIG. 3 (e.g., the offsets having the width W4). The second offsets, in combination with a second thickness of the one or more dies of the stack of dies 115-n as described in connection with FIG. 3 (e.g., the thickness T1), may form an inward facing profile that extends above the substrate 110 toward the central axis 310. In some implementations, using the pick and place tool to form the second shingled stack includes using a die attach film to join dies included in the stack of dies 115-n. Forming the second shingled stack may include forming the tapered wire bond zone 320. Furthermore, and as shown in FIG. 6C, the process 600 may include using a wire bond tool to form at least one wire bond (e.g., the wire bond 315-3) that electrically couples the second shingled stack with the substrate 110.

As shown in FIG. 6D, the process 600 may include forming the casing 120. As an example, and in some implementations, forming the casing 120 includes using a transfer molding tool or an injection molding tool to encapsulate the integrated circuit 105-1, the integrated circuit 105-2a, the integrated circuit 105-2b, the integrated circuit 105-2a, and/or the integrated circuit 105-2d with an epoxy mold compound. In some implementations, and as shown in FIG. 6D, forming the casing 120 fills the tapered wire bond zone 320 and surrounds the wire bond 315-2 with the epoxy mold compound.

As shown in FIG. 6E, the process 600 may include forming the solder balls 140 on the electrical contacts 130. As an example, and in some implementations, forming the solder balls 140 on the electrical contacts includes using a solder ball attach tool to place the solder balls 140 on the electrical contacts 130 and an oven tool to reflow the solder balls 140 and join the solder balls 140 with the electrical contacts 130.

As indicated above, the process steps described in connection with FIG. 6A through FIG. 6E are provided as examples. Other examples may differ from what is described with respect to FIG. 6A through FIG. 6E. The structure shown in FIG. 6E may be equivalent to a portion of the apparatus 100.

In some implementations, a semiconductor device assembly includes a substrate; a first integrated circuit on the substrate having a first overall height, wherein the first integrated circuit includes first semiconductor dies that are stacked and progressively staggered toward a central axis of the substrate; and a second integrated circuit on the substrate having a second overall height that is less than the first overall height, wherein the second integrated circuit includes second semiconductor dies that are stacked and progressively staggered toward the central axis; and wherein the second integrated circuit is between the first integrated circuit and the central axis.

In some implementations, a semiconductor device assembly includes a first stack of first semiconductor dies on a substrate, wherein the first stack has a first stepped profile that extends above the substrate and toward a central axis of the substrate; a second stack of second semiconductor dies on the substrate, wherein the second stack has a second stepped profile that extends above the substrate and toward the central axis of the substrate; and a tapered wire bond zone between the first stack and the second stack, wherein a width of the tapered wire bond zone away from a surface of the substrate is greater than a width of the tapered wire bond zone proximate the surface of the substrate.

In some implementations, an apparatus includes a substrate having a central axis; a first stack of first NAND memory dies that extends upwardly from the substrate, wherein the first NAND memory dies progressively stagger toward the central axis, and wherein each of the first NAND memory dies has a first thickness; and a second stack of second NAND memory dies that extends upwardly from the substrate, wherein the second stack is between the first stack and the central axis, wherein the second NAND memory dies progressively stagger toward the central axis, and wherein each of the second NAND memory dies has a second thickness that is less than the first thickness.

In some implementations, a method includes forming a first shingled stack of first semiconductor dies over a substrate, wherein each of the first semiconductor dies has a first thickness, and wherein an inward facing profile of the first shingled stack extends above the substrate toward a central axis of the substrate; and forming a second shingled stack of second semiconductor die over the substrate, wherein the second shingled stack is between the first shingled stack and an edge of the substrate, wherein each of the second semiconductor dies has a second thickness that is greater than the first thickness, and wherein an inward facing profile of the second shingled stack extends above the substrate toward a central axis of the substrate.

In some implementations, a method includes receiving a semiconductor package including: a substrate; a first integrated circuit on the substrate having a first overall height, wherein the first integrated circuit includes first semiconductor dies that are stacked and progressively staggered toward a central axis of the substrate; and a second integrated circuit on the substrate having a second overall height that is less than the first overall height, wherein the second integrated circuit includes second semiconductor dies that are stacked and progressively staggered toward the central axis, and wherein the second integrated circuit is between the first integrated circuit and the central axis; and joining the semiconductor package with an interface board.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate;
a first integrated circuit on the substrate having a first overall height,
wherein the first integrated circuit includes first semiconductor dies that are stacked and progressively staggered toward a central axis of the substrate; and
a second integrated circuit on the substrate having a second overall height that is less than the first overall height,
wherein the second integrated circuit includes second semiconductor dies that are stacked and progressively staggered toward the central axis; and
wherein the second integrated circuit is between the first integrated circuit and the central axis.

2. The semiconductor device assembly of claim 1, further comprising:
a wire bond that electrically couples the first integrated circuit with the substrate,
wherein the wire bond routes through a tapered wire bond zone between the first integrated circuit and the second integrated circuit.

3. The semiconductor device assembly of claim 2, wherein the tapered wire bond zone extends upwardly from the substrate toward the central axis, and
wherein a width of the tapered wire bond zone increases as the tapered wire bond zone extends away from the substrate.

4. The semiconductor device assembly of claim 1, wherein the first integrated circuit and the second integrated circuit are disposed on a first side of the central axis, and further comprising:
a third integrated circuit on the substrate that is disposed on a second, opposite side of the central axis and that has a same approximate overall height as the first overall height,
wherein the third integrated circuit includes third semiconductor dies that are stacked and progressively staggered toward the central axis of the substrate; and
a fourth integrated circuit on the substrate that is disposed on the second, opposite side and that has a same approximate overall height as the second overall height,
wherein the second integrated circuit includes fourth semiconductor dies that are stacked and progressively staggered toward the central axis of the substrate, and
wherein the fourth integrated circuit is between the third integrated circuit and the central axis.

5. The semiconductor device assembly of claim 4, further comprising:
a fifth integrated circuit on the substrate between the second integrated circuit and the fourth integrated circuit.

6. A semiconductor device assembly, comprising:
a first stack of first semiconductor dies on a substrate,
wherein the first stack has a first stepped profile that extends above the substrate and toward a central axis of the substrate;
a second stack of second semiconductor dies on the substrate,
wherein the second stack has a second stepped profile that extends above the substrate and toward the central axis of the substrate; and
a tapered wire bond zone between the first stack and the second stack,
wherein a width of the tapered wire bond zone away from a surface of the substrate is greater than a width of the tapered wire bond zone proximate the surface of the substrate.

7. The semiconductor device assembly of claim 6, wherein the first stack is between the second stack and the central axis, and
wherein a width of first offsets used to create the first stepped profile is less than or equal to a width of second offsets used to create the second stepped profile.

8. The semiconductor device assembly of claim 6, wherein the first stack of first semiconductor dies and the second stack of second semiconductor dies include a same quantity of semiconductor dies.

9. The semiconductor device assembly of claim 6, wherein the first stack of first semiconductor dies and the second stack of semiconductor dies include different quantities of semiconductor dies.

10. The semiconductor device assembly of claim 6, further comprising:
at least one wire bond within the tapered wire bond zone.

11. The semiconductor device assembly of claim 10, further comprising:
an epoxy mold compound within the tapered wire bond zone,
wherein the epoxy mold compound surrounds the at least one wire bond.

12. An apparatus, comprising:
a substrate having a central axis;
a first stack of first NAND memory dies that extends upwardly from the substrate,
wherein the first NAND memory dies progressively stagger toward the central axis, and
wherein each of the first NAND memory dies has a first thickness; and
a second stack of second NAND memory dies that extends upwardly from the substrate,
wherein the second stack is between the first stack and the central axis,
wherein the second NAND memory dies progressively stagger toward the central axis, and
wherein each of the second NAND memory dies has a second thickness that is less than the first thickness.

13. The apparatus of claim 12, wherein a ratio of a thickness of each NAND memory die of the second NAND memory dies to a thickness of each NAND memory die of the first NAND memory dies is within a range of approximately 9:16 to approximately 11:16.

14. The apparatus of claim 12, further comprising:
a controller die over the substrate and adjacent to a side of the second stack that faces the central axis.

15. The apparatus of claim 14, wherein at least a portion of the second stack extends above and over the controller die.

16. The apparatus of claim 15, wherein a wire bond electrically couples the controller die with the substrate between the controller die and the second stack.

17. A method, comprising:
forming a first shingled stack of first semiconductor dies over a substrate,
wherein each of the first semiconductor dies has a first thickness, and
wherein an inward facing profile of the first shingled stack extends above the substrate toward a central axis of the substrate; and
forming a second shingled stack of second semiconductor die over the substrate,
wherein the second shingled stack is between the first shingled stack and an edge of the substrate,
wherein each of the second semiconductor dies has a second thickness that is greater than the first thickness, and
wherein an inward facing profile of the second shingled stack extends above the substrate toward the central axis of the substrate.

18. The method of claim 17, wherein forming the first shingled stack includes:
joining at least two of the first semiconductor dies using a die attach process that uses a die attach film.

19. The method of claim 17, wherein forming the second shingled stack includes:
joining at least two of the second semiconductor dies using a die attach process that uses a die attach film.

20. The method of claim 17, wherein forming the first shingled stack includes sequentially joining the first semiconductor dies using first offsets having a first width, and
wherein forming the second shingled stack includes:
sequentially joining the second semiconductor dies using second offsets having a second width,
wherein the second width is greater than or equal to the first width.

21. The method of claim 17, wherein forming the second shingled stack includes forming a tapered wire bond zone between an outward facing profile of the first shingled stack and the inward facing profile of the second shingled stack.

22. The method of claim 21, further comprising:
forming a wire bond that electrically couples at least one of the first semiconductor dies with the substrate prior to forming the tapered wire bond zone.

23. The method of claim 22, further comprising:
forming a casing that surrounds the wire bond with an epoxy mold compound and that fills the tapered wire bond zone with the epoxy mold compound.

24. The method of claim 17, wherein the first semiconductor dies and the second semiconductor dies are NAND memory dies, and further comprising:
attaching a controller die to the substrate prior to forming the first shingled stack.

25. The method of claim 24, wherein attaching the controller die to the substrate includes:
attaching the controller die to the substrate using a surface mount process.
